(19) United States
(12) Patent Application Publication
(10) Pub. No.: US 2008/0246392 A1
(43) Pub. Date: Oct. 9, 2008

(54) DONOR SUBSTRATE, METHOD OF FABRICATING THE SAME, AND ORGANIC LIGHT EMITTING DIODE DISPLAY DEVICE

(76) Inventors: Sam-Il Kho, Suwon-si (KR); Jae-Young Cho, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/043,048

(22) Filed: Mar. 5, 2008

(30) Foreign Application Priority Data
Mar. 7, 2007 (KR) 10-2007-0022600

(51) Int. Cl. H01L 27/32; B32B 7/12; B05D 5/06; H05H 1/00

(52) U.S. Cl. 313/504; 428/354; 428/344; 428/336; 427/162; 427/535

(57) ABSTRACT

Provided is a donor substrate, which has high transfer efficiency and increases the reliability of a device, a method of fabricating the same, and an organic light emitting diode (OLED) display device. The donor substrate includes: a base layer; a light-to-heat conversion (LTHC) layer disposed on the base layer; a transfer layer disposed on the LTHC layer and including a color filter layer; and an adhesive layer disposed on the transfer layer.

### CROSS-REFERENCE TO RELATED APPLICATION

This application claims the benefit of Korean Patent Application No. 10-2007-22600, filed Mar. 7, 2007, the disclosure of which is hereby incorporated herein by reference in its entirety.

### BACKGROUND OF THE INVENTION

1. Technical Field

The present disclosure relates to an organic light emitting diode (OLED) display device, and more particularly, to a donor substrate, which has high transfer efficiency and increases the reliability of a device, a method of fabricating the same, and an OLED display device.

2. Description of the Related Art

In order to fabricate a full-color OLED display device, there is a method of forming emission layers corresponding to respective red (R), green (G), and blue (B) colors. However, since R, G, and B emission layers of a full-color OLED display device have different luminous efficiencies (Cd/A), the R, G, and B emission layers exhibit different luminances. The luminance of an emission layer is generally proportional to the current supplied to the emission layer. Thus, even if the same current is supplied, an emission layer of one color typically exhibits a lower luminance, while an emission layer of another color typically exhibits a higher luminance, so that it is difficult to obtain an appropriate color balance or white balance. For example, because the luminous efficiency of a G emission layer is about three to six times higher than the luminous efficiency of an R emission layer and/or a B emission layer, more current should be supplied to the R and/or B emission layers to keep white balance.

In order to solve the problem, an emission layer for emitting single-color light, e.g., white light, and one of a color filter layer and a color conversion layer may be formed. The color filter layer is used to extract light corresponding to a predetermined color from the emission layer, while the color conversion layer is used to convert light emitted by the emission layer into light of a predetermined color.

The color filter layer or the color conversion layer may be formed by a laser induced thermal imaging (LITI) method.

However, when the color filter layer is formed using a typical donor substrate, the adhesion of the color filter layer to a transparent protective layer can be poor so that the color filter layer is easily detached from the transparent protective layer. Also, the OLED display device may be stained with dyestuffs from the color filter layer so that a failure may occur in the OLED display device.

### SUMMARY OF THE INVENTION

Some embodiments provide a donor substrate, a method of fabricating the same, and an organic light emitting diode (OLED) display device. Embodiments of the donor substrate comprise: a base layer; a light-to-heat conversion (LTHC) layer disposed on the base layer; a transfer layer disposed on the LTHC layer, the transfer layer comprising a color filter layer; and an adhesive layer disposed on the transfer layer. Embodiments of the donor substrate exhibit improved transfer and adhesion characteristics, thereby improving reliability of devices comprising the same.

According to one aspect, a donor substrate includes: a base layer; a light-to-heat conversion (LTHC) layer disposed on the base layer; a transfer layer disposed on the LTHC layer and including a color filter layer; and an adhesive layer disposed on the transfer layer.

According to another aspect, a method of fabricating a donor substrate includes: providing a base layer; forming an LTHC layer on the base layer; forming a transfer layer including a color filter layer on the LTHC layer; and forming an adhesive layer on the transfer layer.

According to still another aspect, an OLED display device includes: a substrate; a first electrode disposed on the substrate; an organic layer disposed on the first electrode and including an emission layer; a second electrode disposed on the organic layer; an adhesive layer disposed under the first electrode or on the second electrode; and a color filter layer disposed on the adhesive layer.

Some embodiments provide a donor substrate comprising: a base layer; a light-to-heat conversion (LTHC) layer disposed on the base layer; a transfer layer disposed on the LTHC layer, the transfer layer comprising a color filter layer; and an adhesive layer disposed on the transfer layer.

In some embodiments, the adhesive layer is from about 1 nm to about 5 nm thick. In some embodiments, the adhesive layer comprises at least one of an oxide layer, an argon layer, and a nitride layer.

In some embodiments, the base layer comprises at least one of polyester, polyacrylate, polyepoxy, polyethylene, polystyrene, glass, and polyethylene terephthalate.

In some embodiments, the light-to-heat conversion layer has an optical density of about 2 or less. In some embodiments, the light-to-heat conversion layer comprises at least one of: a metal layer comprising at least one of aluminum, silver, an oxide thereof, and a sulfide thereof; and an organic layer comprising a polymer comprising at least one of carbon black, black lead, and an infrared (IR) dye.

Some embodiments provide a method of fabricating a donor substrate, comprising: providing a base layer; forming a light-to-heat conversion (LTHC) layer on the base layer; forming a transfer layer comprising a color filter layer on the LTHC layer; and forming an adhesive layer on the transfer layer.

In some embodiments, forming the adhesive layer comprises preprocessing the surface of the transfer layer. In some embodiments, preprocessing the surface of the transfer layer comprises at least one of UVO₃ treatment and plasma treatment. In some embodiments, the UVO₃ treatment is performed for from about 10 minutes to about 15 minutes. In some embodiments, the plasma treatment is performed using at least one of O₂ gas, N₂ gas, and Ar gas. In some embodiments, the plasma treatment is performed for from about 0.5 to about 5 minutes. In some embodiments, the plasma treatment is performed at a process pressure of from about 1×10⁻² torr to about 1×10⁻¹ torr. In some embodiments, the plasma treatment is performed at an RF power of from about 180 W to about 250 W.

Some embodiments provide an organic light emitting diode (OLED) display device comprising: a substrate; a first electrode disposed on the substrate; an organic layer disposed on the first electrode, the organic layer comprising an emission layer; a second electrode disposed on the organic layer; an adhesive layer disposed under the first electrode or on the second electrode; and a color filter layer disposed on the adhesive layer.

In some embodiments, the adhesive layer is from 1 nm to about 5 nm thick. In some embodiments, the adhesive layer comprises at least one of an oxide layer, an argon layer, and a nitride layer.

Some embodiments further comprise a transparent protective layer disposed under the adhesive layer.

In some embodiments, the first electrode comprises at least two layers.

In some embodiments, the emission layer comprises a phosphorescent emission layer and a fluorescent emission layer.

### BRIEF DESCRIPTION OF THE DRAWINGS

The above and other features will be described in reference to certain exemplary embodiments thereof with reference to the attached drawings in which:

FIG. 1 is a cross-sectional view of a donor substrate according to an exemplary embodiment;

FIGS. 2A and 2B are cross-sectional views illustrating a method of fabricating a top-emitting organic light emitting diode (OLED) display device using a donor substrate according to an exemplary embodiment;

FIGS. 3A and 3B are cross-sectional views illustrating a method of fabricating a bottom-emitting OLED display device using a donor substrate according to an exemplary embodiment;

FIG. 4 is a photograph showing the adhesion of a color filter layer to a substrate according to Example 1;

FIG. 5 is a photograph showing the adhesion of a color filter layer to a first electrode according to Example 2;

FIG. 6 is a photograph showing the adhesion of a color filter layer to a substrate according to Example 3; and

FIG. 7 is a photograph showing the adhesion of a color filter layer to a substrate according to Comparative Example 1.

### DETAILED DESCRIPTION OF CERTAIN EMBODIMENTS

Certain embodiments will now be described more fully hereinafter with reference to the accompanying drawings, in which exemplary embodiments are shown.

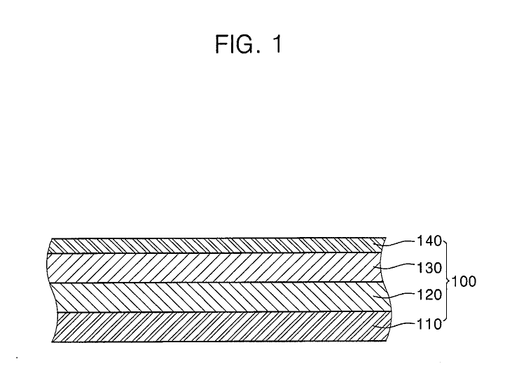

FIG. 1 is a cross-sectional view of a donor substrate 100 according to an exemplary embodiment.

Referring to FIG. 1, a donor substrate 100 includes a base layer 110, a light-to-heat conversion (LTHC) layer 120, a transfer layer 130, and an adhesive layer 140, which are stacked sequentially.

The base layer 110 functions as a support substrate and is formed of a transparent material to transmit light to the LTHC layer 120. Also, the base layer 110 may comprise a material having high mechanical stability. For example, the base layer 110 may comprise at least one of polyester, polyacrylate, polyepoxy, polyethylene, polystyrene, and glass. In particular, the base layer 110 may comprise polyethylene terephthalate (PET).

The LTHC layer 120 absorbs light in the infrared-visible light range and converts part of the light into heat. The LTHC layer 120 may comprise a light absorbing material. For instance, the LTHC layer 120 may be a metal layer comprising at least one of Al, Ag, an oxide thereof, and a sulfide thereof, and an organic layer comprising a polymer containing carbon black, black lead, or an infrared (IR) dye. The metal layer may be obtained using a vacuum evaporation method, an electronic beam (e-beam) evaporation method, and/or a sputtering method. The organic layer may be obtained using a typical film coating method, such as a Gravure coating method, an extrusion coating method, a spin coating method, or a knife coating method. Also, the LTHC layer 120 may have an optical density of about 2 or less to reduce thermal damage on the transfer layer 130.

The transfer layer 130 is disposed on the LTHC layer 120 and includes a color filter layer. The color filter layer may include a pigment and a polymer binder. The color filter layer may be categorized as a red (R) color filter layer, a green (G) color filter layer, and/or a blue (B) color filter layer according to the type of the pigment. The R, G, and B color filter layers transmit incident light emitted by an emission layer at R, G, and B wavelength ranges, respectively.

The adhesive layer 140 is disposed on the transfer layer 130. The adhesive layer 140 functions to improve the adhesion of the transfer layer 130 to a substrate during a laser induced thermal imaging (LITI) process. Also, the adhesive layer 140 does not exhibit its own color and has a thickness of from about 1 nm to about 5 nm to improve the adhesion of the transfer layer 130 to the substrate.

The adhesive layer 140 may be formed by preprocessing the surface of the transfer layer 130 using UVO₃ and/or plasma. The UVO₃ treatment of the surface of the transfer layer 130 may be performed for from about 10 minutes to about 15 minutes so that the adhesive layer 140 may comprise an oxide layer to have a thickness of from about 1 nm to about 5 nm.

An embodiment of a plasma treatment of the surface of the transfer layer 130 to form the adhesive layer 140 will now be described. Initially, the donor substrate 100 having the transfer layer 130 is loaded into a plasma processing reactor, and gases are exhausted from the plasma processing reactor to reach a predetermined vacuum pressure. Thereafter, O₂, Ar, and/or N₂ is supplied at a flow rate of from about 10 sccm to about 100 sccm through a gas supply line to a plasma generation space. Then, the plasma processing reactor is maintained under a process pressure of from about 1×10⁻² torr to about 1×10⁻¹ torr. An RF power of from about 180 W to about 250 W is applied to a plasma generator to generate an O₂ plasma, Ar plasma, and/or N₂ plasma in the plasma generation space so that an oxide layer, an argon layer, and/or a nitride layer is formed as the adhesive layer 140 on the surface of the transfer layer 130. The terms “oxide layer”, “argon layer”, and “nitride layer” refer to layers formed by treatment with an oxygen plasma, an argon plasma, or a nitrogen plasma as described above, respectively. In this case, the surface of the transfer layer 130 is processed using plasma for from about 30 seconds to about 5 minutes. As a result, the adhesive layer 140 can be formed to a thickness of from about 1 nm to about 5 nm.

In this process, the donor substrate according to the exemplary embodiment of the present invention can be completed.

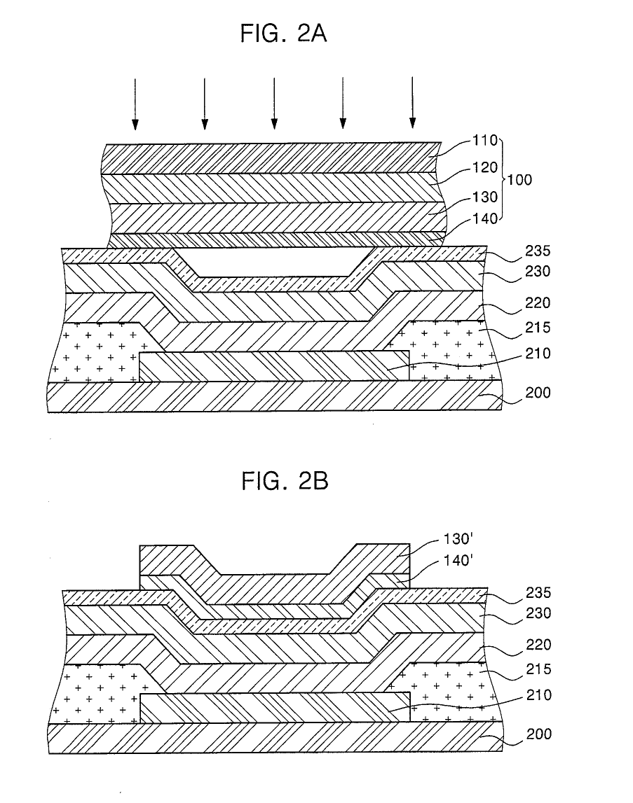

FIGS. 2A and 2B are cross-sectional views illustrating a method of fabricating a top-emitting organic light emitting diode (OLED) display device using a donor substrate according to an exemplary embodiment.

Referring to FIG. 2A, a substrate 200 is provided, and a first electrode 210 is formed on the substrate 200. The first electrode 210 may be a double structure or a triple structure. The first electrode 210 may be a double structure including a reflective layer and a transparent conductive layer which are sequentially stacked. The reflective layer may be formed of Al, Ag, and/or an alloy thereof, and the transparent conductive layer may comprise indium tin oxide (ITO), indium zinc oxide (IZO), and/or indium tin zinc oxide (ITZO). Alternatively, the first electrode 210 may be a triple structure including a first metal layer, a second metal layer, and a third metal layer which are sequentially stacked. The first metal layer may comprise Ti, Mo, ITO, and/or an alloy thereof, the second metal layer may comprise Al, Ag, and/or an alloy thereof, and the third metal layer may comprise ITO, IZO, and/or ITZO.

An insulating layer, a capacitor, and a thin film transistor (TFT) may be further formed between the substrate 200 and the first electrode 210.

A pixel defining layer 215 is formed on the first electrode 210 and patterned to form an opening that exposes at least a portion of the first electrode 210. The pixel defining layer 215 may be an organic layer and/or an inorganic layer. The organic layer may comprise at least one of polyimide, a benzocyclobutene (BCB)-series resin, and acrylate, and the inorganic layer may comprise a silicate on glass (SOG).

An organic layer 220 including a white emission layer is formed on the first electrode 210. The white emission layer may be a single layer or a multiple layer. In embodiments in which the white emission layer is a single layer, white light may be obtained by adding a dopant to emission materials for emitting light of different colors or by mixing poly(N-vinylcarbazole) (PVK) with PBD, TPB, Coumarin 6, DCM1, and/or Nile red in an appropriate ratio. Alternatively, emission materials of two different colors are mixed and another emission material may be added to the mixture to obtain a white emission material. For example, an R emission material is mixed with a G emission material, and a B emission material is added to the mixture of the R and G emission materials so that a white emission material can be obtained. The R emission material comprises polythiophene (PT), which is a polymer, and derivatives thereof. Also, the G emission material comprises at least one of Alq3, BeBq2, and Almq, which are low molecular weight materials, and poly(p-phenylene)vinylene (PPV), which is a polymer, and derivatives thereof. Also, the B emission material comprises at least one of ZnPBO, Balq, DPVBi, and OXA-D, which are low molecular weight materials, and poly(p-phenylene) (PPP), which is a polymer, and derivatives thereof.

In embodiments in which the white emission layer comprises multiple layers, the white emission layer may include two layers that emit light in different wavelength ranges. One layer of the white emission layer may be a phosphorescent emission layer that emits light in the orange-red wavelength range, and the other layer thereof may be a fluorescent emission layer that emits light in the blue wavelength range, for example. Typically, a phosphorescent emission layer has better emission characteristics and a shorter lifetime than a fluorescent emission layer that emits light in the same wavelength range. Thus, the white emission layer can have high luminous efficiency and long lifetime when the white emission layer is formed by stacking a phosphorescent emission layer emitting light in the orange-red wavelength range and a fluorescent emission layer emitting light in the blue wavelength range. Also, the white emission layer may be a double layer comprising only polymers, only low molecular weight materials, or both a low molecular weight material and a polymer.

When the white emission layer comprises a triple layer, the white emission layer may be formed by stacking an R emission layer, a G emission layer, and a B emission layer. Those skilled in the art will understand that other stacking orders of the R, G, and B emission layers are used in other embodiments.

The R emission layer may comprise a low molecular weight material, such as Alq3(host)/DCJTB(fluorescent dopant), Alq3(host)/DCM(fluorescent dopant), and CBP(host)/PtOEP(phosphorescent organic metal complex), and/or a polymer, such as a polyfluorene (PFO)-based polymer and/or a PPV-based polymer.

The G emission layer may comprise a low molecular material, such as Alq3, Alq3(host)/C545t(dopant), CBP(host)/IrPPY(phosphorescent organic material complex), and/or a polymer, such as a PFO-based polymer and/or a PPV-based polymer.

Also, the B emission layer may comprise a low molecular material, such as DPVBi, Spiro-DPVBi, Spiro-6P, distyryl-benzene(DSB), and/or distyryl-arylene (DSA), and/or a polymer, such as a PFO-based polymer and/or a PPV-based polymer.

The organic layer 220 may include at least one of a hole injection layer, a hole transport layer, a hole blocking layer, an electron transport layer, and an electron injection layer. The organic layer 220 may be formed using at least one of an LITI process, an inkjet printing process, and a vacuum evaporation process.

A second electrode 230, which is a semi-transmissive electrode in the illustrated embodiment, is formed on the organic layer 220. The second electrode 230 may comprise magnesium silver (MgAg) and/or aluminum silver (AlAg). Thus, the second electrode 230 may be formed, for example, by co-depositing a Mg layer and an Ag layer, or sequentially depositing an Al layer and an Ag layer. Also, a transparent conductive layer comprising ITO and/or IZO may be further formed on the second electrode 230.

A transparent protective layer 235 is formed on the second electrode 230. The transparent protective layer 235 may comprise an inorganic layer, an organic layer, and/or an organic-inorganic composite layer. The inorganic layer may comprise at least one of ITO, IZO, SiO₂, SiNₓ, Y₂O₃, and Al₂O₃, the organic layer may comprise at least one of parylene and high-density polyethylene (HDPE), and the organic-inorganic composite layer may comprise a composite layer of Al₂O₃ and an organic polymer.

Meanwhile, a donor substrate 100, including a base layer 110, a light-to-heat conversion (LTHC) layer 120, a transfer layer 130 having a color filter layer, and an adhesive layer 140, is provided. The adhesive layer 140 may comprise a plasma-modified layer as described above, for example, at least one of an oxide layer, an argon layer, and a nitride layer, with a thickness of from about 1 nm to about 5 nm. The donor substrate 100 is described in detail above with reference to FIG. 1.

The donor substrate 100 is disposed on the transparent protective layer 235 such that the adhesive layer 140 of the donor substrate 100 is disposed on a surface thereof opposite to the transparent protective layer 235 in a region corresponding to the first electrode 210.

Referring to FIG. 2B, a portion of the base layer 110 is irradiated, for example, using laser beams, transferring the transfer layer 130 and the adhesive layer 140 to the transparent protective layer 235, thereby forming a transfer layer pattern 130′, which comprises a color filter layer, and an adhesive layer pattern 140′.

Thereafter, the top-emitting OLED display device according to the illustrated embodiment can be completed by encapsulating the transfer layer pattern 130′ and the adhesive layer pattern 140′.

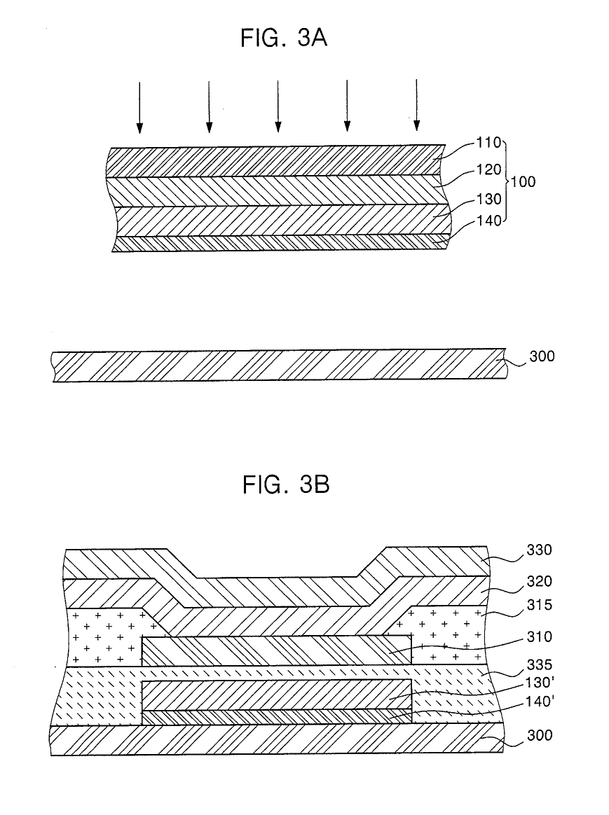

FIGS. 3A and 3B are cross-sectional views illustrating a method of fabricating a bottom-emitting OLED display device using a donor substrate according to an exemplary embodiment.

Referring to FIG. 3A, a transparent substrate 300, which comprises glass, stainless steel, and/or plastic, is provided. Meanwhile, a donor substrate 100, including a base layer 110, an LTHC layer 120, a transfer layer 130 having a color filter layer, and an adhesive layer 140, is provided.

The adhesive layer 140 may comprise a plasma-modified layer as described above, for example, at least one of an oxide layer, an argon layer, and a nitride layer, with a thickness of from about 1 nm to about 5 nm. The donor substrate 100 is described in detail above with reference to FIG. 1. Thereafter, the substrate 300 and the donor substrate 100 are disposed on opposite surfaces of the adhesive layer 140.

Referring to FIG. 3B, a portion of the base layer 110 is irradiated, for example, using laser beams, transferring the transfer layer 130 and the adhesive layer 140 to the substrate 300, thereby forming a transfer layer pattern 130′, which comprises a color filter layer, and an adhesive layer pattern 140′.

A transparent protective layer 335 is formed on the substrate 300 including the transfer layer pattern 130′. The transparent protective layer 335 may comprise an inorganic layer, an organic layer, and/or an organic-inorganic composite layer. The inorganic layer may comprise at least one of ITO, IZO, SiO₂, SiNₓ, Y₂O₃, and Al₂O₃; the organic layer may comprise at least one of parylene and HDPE; and the organic-inorganic composite layer may comprise a composite layer of Al₂O₃ and an organic polymer.

A first electrode 310 is formed on a region of the transparent protective layer 335 corresponding to the color filter layer 130′. The first electrode 310 comprises a transmissive electrode material having a large work function, for example, at least one of ITO, IZO, and ITZO.

A pixel defining layer 315 is formed on the first electrode 310 and patterned to form an opening exposing a portion of the first electrode 310. The pixel defining layer 315 may comprise an organic layer or an inorganic layer. The organic layer may comprise at least one of polyimide, BCB-series resin, and acrylate, and the inorganic layer may be formed of silicate on glass (SOG).

An organic layer 320, which comprises a white emission layer, is formed on the first electrode 310. The white emission layer may comprise a single layer, a double layer, or a triple layer. The white emission layer is described in detail above with reference to FIG. 2B.

The organic layer 320 may include at least one of a hole injection layer, a hole transport layer, a hole blocking layer, an electron transport layer, and an electron injection layer. The organic layer 320 is described in detail above with reference to FIG. 2B.

A second electrode 330 is formed on the organic layer 320. The second electrode 330 may comprise a material having a small work function, for example, at least one of Al, Ag, Mg, Ca, and Ba.

In this process, the bottom-emitting OLED display device using the donor substrate 100 according to the embodiment of the present invention can be completed.

Hereinafter, non-limiting examples will be described.

### EXAMPLE 1

A donor substrate was prepared by coating a color filter layer material (3M) on a substrate (3M) including a base layer and an LTHC layer to form a transfer layer including a color filter layer. The surface of the transfer layer was processed using UVO₃ for 12 minutes to form an adhesive layer having a thickness of about 3 nm. Thus, the donor substrate was completed.

The donor substrate was positioned on a substrate with the adhesive layer of the donor substrate disposed between the substrate and the color filter layer of the donor substrate. The donor substrate was irradiated with Nd-YAG laser beams so that the transfer layer and the adhesive layer were transferred to the substrate. The transfer process was performed with a laser power of 10 W at a scan rate of 7 m/sec.

### EXAMPLE 2

A donor substrate including a first electrode was prepared by coating a color filter layer material (3M) on a substrate (3M) including a base layer and an LTHC layer to form a transfer layer including a color filter layer. The surface of the transfer layer was processed using UVO₃ for 12 minutes to form an adhesive layer having a thickness of about 3 nm. Thus, a donor substrate was completed.

The donor substrate was positioned on a substrate with the adhesive layer of the donor substrate disposed between the substrate and the color filter layer of the donor substrate. The donor substrate was irradiated with Nd-YAG laser beams so that the transfer layer and the adhesive layer were transferred to the substrate. The transfer process was performed with a laser power of 10 W at a scan rate of 7 m/sec.

### EXAMPLE 3

A donor substrate was prepared by coating a color filter layer material (3M) on a substrate (3M) including a base layer and an LTHC layer to form a transfer layer including a color filter layer. The donor substrate including the transfer layer was loaded into a plasma processing reactor, and O₂ was supplied at a flow rate of 50 sccm through a gas supply line to a plasma generation space. Also, the plasma processing reactor was maintained under a pressure of 1×10⁻² torr. Thereafter, an RF power of 200 W was applied to the plasma generation space so that O₂ plasma was generated for 3 minutes, thereby forming an adhesive layer having a thickness of about 3 nm. Thus, a donor substrate was completed.

The donor substrate was positioned on a substrate with the adhesive layer of the donor substrate disposed between the substrate and the color filter layer of the donor substrate. The donor substrate was irradiated with Nd-YAG laser beams so that the transfer layer and the adhesive layer were transferred to the substrate. The transfer process was performed with a laser power of 10 W at a scan rate of 7 m/sec.

### COMPARATIVE EXAMPLE

A donor substrate was prepared by coating a color filter layer material (3M) on a substrate (3M) including a base layer and an LTHC layer to form a transfer layer including a color filter layer so that a donor substrate was completed.

The donor substrate was positioned such that the transfer layer of the donor substrate was disposed directly on the substrate. The donor substrate was irradiated with Nd-YAG laser beams so that the transfer layer and the adhesive layer were transferred to the substrate. The transfer process was performed with a laser power of 10 W at a scan rate of 7 m/sec.

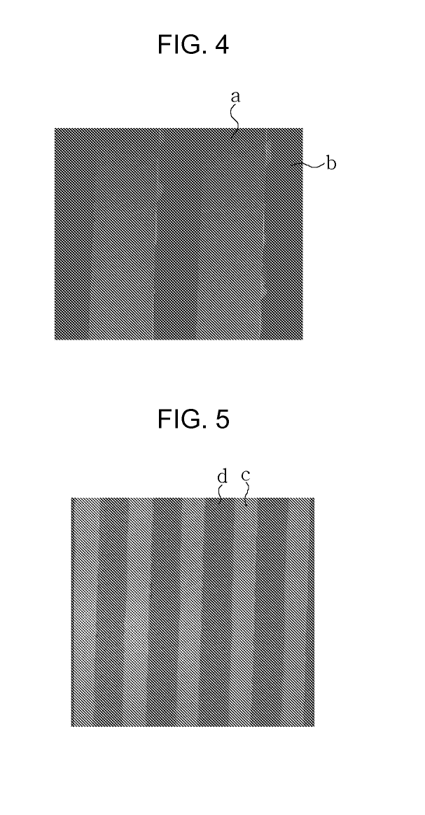

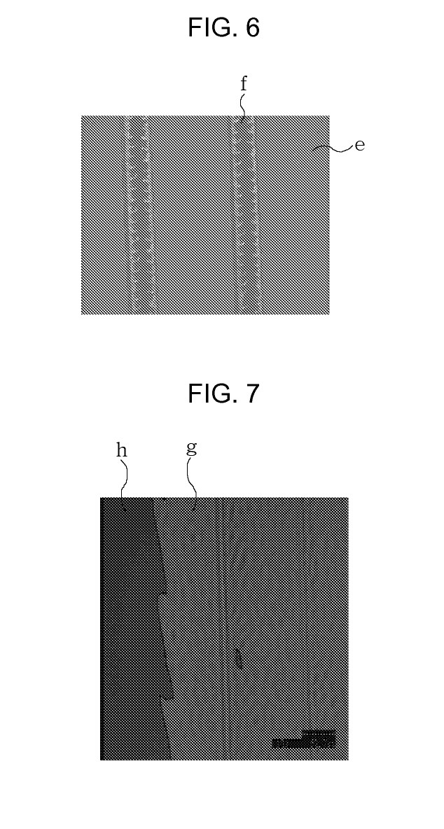

FIG. 4 is a photograph showing the adhesion of the color filter layer “b” to the substrate “a” according to Example 1. FIG. 5 is a photograph showing the adhesion of the color filter layer “d” to the first electrode “c” according to Example 2. FIG. 6 is a photograph showing the adhesion of the color filter layer “f” to the substrate “e” according to Example 3. Also, FIG. 7 is a photograph showing the adhesion of the color filter layer “h” to the substrate “g” according to Comparative example.

Referring to FIG. 4, according to Example 1, the adhesion of the color filter layer “b” to the substrate “a” is good, as indicated by a boundary line between the color filter layer “b” and the substrate “a” that is barely observable. Referring to FIG. 5, according to Example 2, the adhesion of the color filter layer “d” to the first electrode “c” is good, as indicated by no observable boundary line between the color filter layer “d” and the first electrode “c”. Referring to FIG. 6, according to Example 3, the adhesion of the color filter layer “f” to the substrate “e” is good, as indicated by a boundary line between the color filter layer “b” and the substrate “a” that is barely observable. In contrast, referring to FIG. 7, according to the Comparative Example, the adhesion of the color filter layer “h” to the substrate “g” is poor so that an evident boundary line between the color filter layer “h” and the substrate “g” is observed.

As described above, embodiments of a donor substrate including an adhesive layer that is formed by processing the surface of the transfer layer including a color filter layer not only exhibit improved transfer efficiency, but also improved adhesion of the color filter layer to the substrate.

According to some embodiments, an adhesive layer is further formed on a donor substrate by preprocessing the surface of a transfer layer including a color filter layer. As a result, transfer quality and the adhesion of the color filter layer to a substrate can be improved, thereby increasing the reliability of an OLED display device. Some embodiments can be applied to a double-sided emitting OLED display device.

Although certain embodiments have been described with reference to certain exemplary embodiments, it will be understood by those skilled in the art that a variety of modifications and variations may be made without departing from the spirit or scope of the present disclosure as defined in the appended claims, and their equivalents.

What is claimed is:

1. A donor substrate comprising:
a base layer;
a light-to-heat conversion (LTHC) layer disposed on the base layer;
a transfer layer disposed on the LTHC layer, the transfer layer comprising a color filter layer; and
an adhesive layer disposed on the transfer layer.

2. The donor substrate according to claim 1, wherein the adhesive layer is from about 1 nm to about 5 nm thick.

3. The donor substrate according to claim 1, wherein the adhesive layer comprises at least one of an oxide layer, an argon layer, and a nitride layer.

4. The donor substrate according to claim 1, wherein the base layer comprises at least one of polyester, polyacrylate, polyepoxy, polyethylene, polystyrene, glass, and polyethylene terephthalate.

5. The donor substrate according to claim 1, wherein the light-to-heat conversion layer has an optical density of about 2 or less.

6. The donor substrate according to claim 1, wherein the light-to-heat conversion layer comprises at least one of:
a metal layer comprising at least one of aluminum, silver, an oxide thereof, and a sulfide thereof, and
an organic layer comprising a polymer comprising at least one of carbon black, black lead, and an infrared (IR) dye.

7. A method of fabricating a donor substrate, comprising:
providing a base layer;
forming a light-to-heat conversion (LTHC) layer on the base layer;
forming a transfer layer comprising a color filter layer on the LTHC layer; and
forming an adhesive layer on the transfer layer.

8. The method according to claim 7, wherein forming the adhesive layer comprises preprocessing the surface of the transfer layer.

9. The method according to claim 7, wherein preprocessing the surface of the transfer layer comprises at least one of UVO₃ treatment and plasma treatment.

10. The method according to claim 9, wherein the UVO₃ treatment is performed for from about 10 minutes to about 15 minutes.

11. The method according to claim 9, wherein the plasma treatment is performed using at least one of O₂ gas, N₂ gas, and Ar gas.

12. The method according to claim 9, wherein the plasma treatment is performed for from about 0.5 to about 5 minutes.

13. The method according to claim 9, wherein the plasma treatment is performed at a process pressure of from about 1×10⁻² torr to about 1×10⁻¹ torr.

14. The method according to claim 9, wherein the plasma treatment is performed at an RF power of from about 180 W to about 250 W.

15. An organic light emitting diode (OLED) display device comprising:
a substrate;
a first electrode disposed on the substrate;
an organic layer disposed on the first electrode, the organic layer comprising an emission layer;
a second electrode disposed on the organic layer;
an adhesive layer disposed under the first electrode or on the second electrode; and
a color filter layer disposed on the adhesive layer.

16. The OLED display device according to claim 15, wherein the adhesive layer is from 1 nm to about 5 nm thick.

17. The OLED display device according to claim 15, wherein the adhesive layer comprises at least one of an oxide layer, an argon layer, and a nitride layer.

18. The OLED display device according to claim 15, further comprising a transparent protective layer disposed under the adhesive layer.

19. The OLED display device according to claim 15, wherein the first electrode comprises at least two layers.

20. The OLED display device according to claim 15, wherein the emission layer comprises a phosphorescent emission layer and a fluorescent emission layer.
